(19) United States
(12) Patent Application Publication
(10) Pub. No.: US 2010/0122723 A1
(43) Pub. Date: May 20, 2010

(54) Photovoltaic Power for Communications Networks

(76) Inventors: Arkadiusz Rudy Sadkowski, Chicago, IL (US); Gerald Gottsteia, Springfoeld, IL (US); Jeanne Muellner, Orladn Park, IL (US)

Correspondence Address: AT&T Legal Department - SZ;Attn: Patent Docketing, Room 2A-207, One AT&T Way, Bedminster, NJ, 07921, US

(21) Appl. No.: 12/270,902

(22) Filed: Nov. 14, 2008

(51) Int. Cl. H01L 31/00

(52) U.S. Cl. 136/252

(57) ABSTRACT

Methods, systems, and products are disclosed for providing photovoltaic power to a communications network. AC electrical power is measured that is consumed in a rectifier that produces a DC output to a telephony transmission line. The DC output is measured in the telephony transmission line. Photovoltaic power is measured that is produced by a photovoltaic device that is applied to the telephony transmission line. The consumption of the AC electrical power in the rectifier is reduced in response to the photovoltaic power produced by the photovoltaic device.

### NOTICE OF COPYRIGHT PROTECTION

A portion of the disclosure of this patent document and its figures contain material subject to copyright protection. The copyright owner has no objection to the facsimile reproduction by anyone of the patent document or the patent disclosure, but otherwise reserves all copyrights whatsoever.

### BACKGROUND

Exemplary embodiments generally relate to communications and to electricity and, more particularly, to circuit amplification, to telephony subscriber lines, to voltage boosting circuits, to transmission line power supplies, to ringing circuitry, to photoelectric batteries, and to solar-sourced electricity.

Communications networks use a lot of electricity. A telephone network, for example, operates by applying electrical voltage to telephone lines, and the electrical voltage causes some network devices to provide the telephone service we all use. Packet-based networks also utilize current and voltage as signals to communicate our emails, pages, and other forms of electronic communications. Wireless networks, too, require electrical power to transmit electromagnetic signals to cell phones and to other wireless devices. Because these communications networks rely on electricity, communications networks may be connected to the electrical grid. The electrical grid provides electricity that is needed for our communications services. The network providers who operate and maintain these communications networks thus spend millions of dollars per year in electricity costs. Network providers thus embrace concepts that reduce their consumption of electricity.

### SUMMARY

Exemplary embodiments provide methods, systems, apparatuses, and products for providing supplemental electrical power to any system. The system consumes electrical power from the electrical grid. Exemplary embodiments, however, supplement the electrical needs of the system using photovoltaic power. The photovoltaic power is produced by a photovoltaic device, such as solar cells. When the photovoltaic power is provided to the system, the photovoltaic power supplements the electrical needs of the system. The electrical power consumed from the electrical grid may thus be reduced according to the photovoltaic power produced by the photovoltaic device.

Exemplary embodiments include a method of providing photovoltaic power in a communications network. AC electrical power is consumed at a rectifier in the communications network. Photovoltaic power, produced by a photovoltaic device, is received. The consumption of the AC electrical power is reduced in response to the photovoltaic power produced by the photovoltaic device.

Other exemplary embodiments include a system providing photovoltaic power to a communications network. A rectifier consumes an AC input to produce a DC output. A photovoltaic device produces an output. A first transmission line provides a parallel connection between the DC output from the rectifier and the output from the photovoltaic device. The AC input consumed by the rectifier is reduced by an amount of power produced by the output of the photovoltaic device.

More exemplary embodiments include a computer readable storage medium that stores processor-executable instructions for performing a method of providing photovoltaic power to a communications network. Consumption of AC electrical power is measured in a rectifier that produces a DC output to a telephony transmission line. The DC output in the telephony transmission line is measured. Photovoltaic power produced by a photovoltaic device is measured that is applied to the telephony transmission line. The consumption of the AC electrical power in the rectifier is reduced in response to the photovoltaic power produced by the photovoltaic device.

Other systems, methods, and/or computer program products according to the exemplary embodiments will be or become apparent to one with ordinary skill in the art upon review of the following drawings and detailed description. It is intended that all such additional systems, methods, and/or computer program products be included within this description, be within the scope of the claims, and be protected by the accompanying claims.

### BRIEF DESCRIPTION OF THE SEVERAL VIEWS OF THE DRAWINGS

These and other features, aspects, and advantages of the exemplary embodiments are better understood when the following Detailed Description is read with reference to the accompanying drawings, wherein:

FIG. 1 is a simplified schematic illustrating a supplemental photovoltaic power source, according to exemplary embodiments;

FIG. 2 is a schematic illustrating supplemental photovoltaic power for a communications network, according to exemplary embodiments;

FIG. 3, for example, is a simplified schematic illustrating supplemental photovoltaic power for a telephony network, according to exemplary embodiments;

FIG. 4 is a block diagram further illustrating a feedback mechanism, according to exemplary embodiments;

FIGS. 5 and 6 are more detailed schematic illustrating supplemental photovoltaic power for the telephony network, according to exemplary embodiments;

FIG. 7 is a flowchart illustrating a method of providing supplemental electrical power, according to exemplary embodiments;

FIG. 8 illustrates other operating environments, according to exemplary embodiments; and

FIG. 9 is a schematic illustrating a graphical user interface 300, according to exemplary embodiments.

### DETAILED DESCRIPTION

The exemplary embodiments will now be described more fully hereinafter with reference to the accompanying drawings. The exemplary embodiments may, however, be embodied in many different forms and should not be construed as limited to the embodiments set forth herein. These embodiments are provided so that this disclosure will be thorough and complete and will fully convey the exemplary embodiments to those of ordinary skill in the art. Moreover, all statements herein reciting embodiments, as well as specific examples thereof, are intended to encompass both structural and functional equivalents thereof. Additionally, it is intended that such equivalents include both currently known equivalents as well as equivalents developed in the future (i.e., any elements developed that perform the same function, regardless of structure).

Thus, for example, it will be appreciated by those of ordinary skill in the art that the diagrams, schematics, illustrations, and the like represent conceptual views or processes illustrating the exemplary embodiments. Those of ordinary skill in the art further understand that the exemplary hardware, software, processes, methods, and/or operating systems described herein are for illustrative purposes and, thus, are not intended to be limited to any particular named manufacturer.

As used herein, the singular forms “a,” “an,” and “the” are intended to include the plural forms as well, unless expressly stated otherwise. It will be further understood that the terms “includes,” “comprises,” “including,” and/or “comprising,” when used in this specification, specify the presence of stated features, integers, steps, operations, elements, and/or components, but do not preclude the presence or addition of one or more other features, integers, steps, operations, elements, components, and/or groups thereof. It will be understood that when an element is referred to as being “connected” or “coupled” to another element, it can be directly connected or coupled to the other element or intervening elements may be present. Furthermore, “connected” or “coupled” as used herein may include wirelessly connected or coupled. As used herein, the term “and/or” includes any and all combinations of one or more of the associated listed items.

It will also be understood that, although the terms first, second, etc. may be used herein to describe various elements, these elements should not be limited by these terms. These terms are only used to distinguish one element from another. For example, a first device could be termed a second device, and, similarly, a second device could be termed a first device without departing from the teachings of the disclosure.

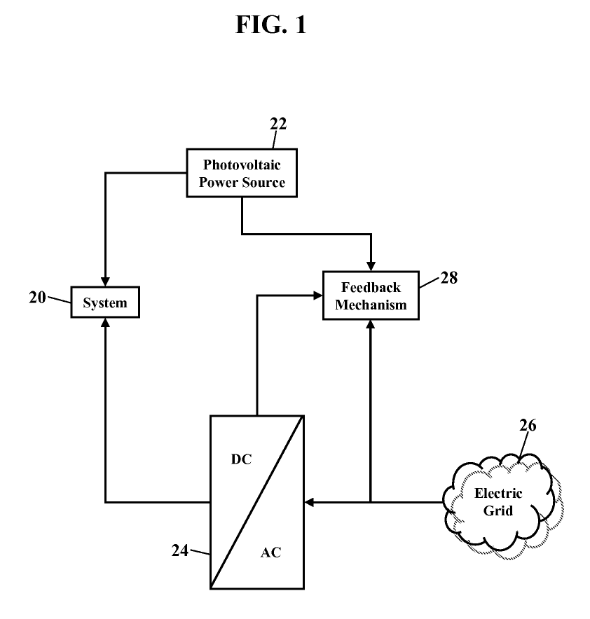

FIG. 1 is a simplified schematic illustrating a supplemental photovoltaic power source, according to exemplary embodiments. FIG. 1 illustrates a system 20 that receives electrical power from a photovoltaic power source 22 and from a rectifier 24. FIG. 1 only generically illustrates the system 20, as the system 20 may be any mechanical, electrical, chemical, and/or biological system that uses electrical power to produce an output, provide a service, or even grow or multiply. As those of ordinary skill in the art understand, the photovoltaic power source 22 absorbs optical energy and outputs electrical power (e.g., current and/or voltage) to the system 20. Most readers are familiar with solar cells and solar panels, which are photovoltaic devices that convert the sun's solar energy into electrical energy. As those of ordinary skill in the art also understand, the rectifier 24 receives alternating current (“AC”) electrical power from a power source and converts, or “rectifies,” the AC electrical power into direct current (“DC”) electrical power. FIG. 1 illustrates the rectifier 24 receiving AC electrical power from an electric grid 26. The electric grid 26 is typically provided, for example, by an electric utility. The rectifier 24, of course, may additionally or alternatively receive AC electrical power from other sources, such as a generator or another photovoltaic power source. Regardless, as the operations of both the photovoltaic power source 22 and the rectifier 24 are well-known, neither is described in great detail.

FIG. 1 also illustrates a feedback mechanism 28. The feedback mechanism 28 senses, detects, or is informed of the amount of photovoltaic power produced by the photovoltaic power source 22. The feedback mechanism 28 also senses, detects, or is informed of the amount of DC power produced by the rectifier 24. The feedback mechanism 28 compares the DC output from the rectifier 24 to the photovoltaic power produced by the photovoltaic power source 22. The feedback mechanism 28 may then reduce the DC output from the rectifier 24 by an amount equal to the photovoltaic power produced by the photovoltaic power source 22. Because the DC output from the rectifier 24 may be proportionally or correspondingly reduced, the feedback mechanism 28 also causes a reduction in the consumption of the AC electrical power in the rectifier 24. The photovoltaic power source 22, in other words, supplements the electrical power required by the system 20 and reduces the consumption of electricity by the rectifier 24. Because the rectifier 24 consumes less AC electrical power from the electric grid 26, exemplary embodiments cause a reduction in electricity costs for operating the system 20.

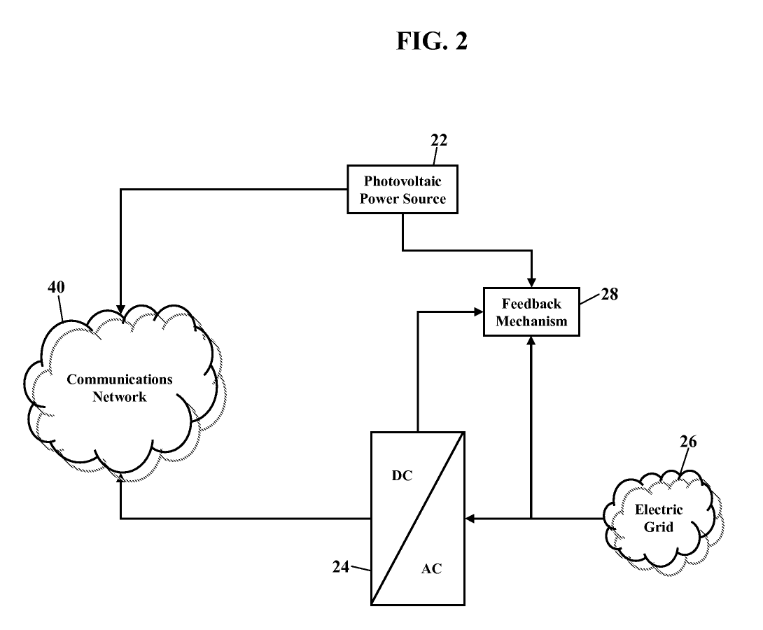

FIG. 2 is a schematic illustrating supplemental photovoltaic power for a communications network 40, according to exemplary embodiments. Here the communications network 40 receives electrical power from both the photovoltaic power source 22 and from the rectifier 24. The feedback mechanism 28 measures the photovoltaic power produced by the photovoltaic power source 22. The feedback mechanism 28 also measures the DC power produced by the rectifier 24. Because the photovoltaic power source 22 provides supplemental electrical power to the communications network 40, the feedback mechanism 28 may reduce the DC output produced by the rectifier 24. Because the rectifier 24 produces less DC output, the rectifier 24 may consume less AC electrical power from the electric grid 26. The electricity costs for operating the rectifier 24 are correspondingly reduced.

Exemplary embodiments may be applied to any networking environment. The communications network 40, for example, may be a telephony network that uses metallic cables or wires. The communications network 40, however, may also be a cable network operating in the radio-frequency domain and/or the Internet Protocol (IP) domain. The communications network 40, however, may also include fiber optic lines and/or hybrid-coaxial lines. The communications network 40 may even include wireless portions utilizing any portion of the electromagnetic spectrum and any signaling standard (such as the I.E.E.E. 802 family of standards, GSM/CDMA/TDMA or any cellular standard, and/or the ISM band). The communications network 40 may even include powerline portions, in which signals are communicated via electrical wiring. The concepts described herein may be applied to any wireless/wireline communications network, regardless of physical componentry, physical configuration, or communications standard(s).

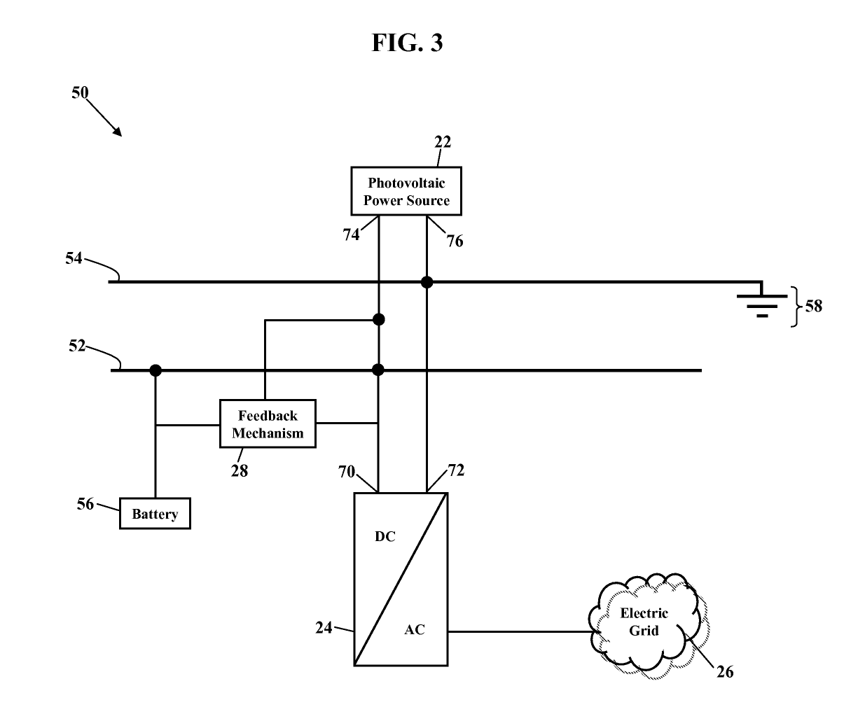

FIG. 3, for example, is a simplified schematic illustrating supplemental photovoltaic power for a telephony network 50, according to exemplary embodiments. The telephony network 50 comprises a first transmission line 52 and a second transmission line 54. The first transmission line 52, for example, may be a ring line and/or tip line of the telephony network 50. The ring and tip lines of the telephony network 50 are well-known conductors in the telephony network 50 and, thus, not further described. One or more batteries 56 may be connected to the first transmission line 52 to provide a biasing voltage. FIG. 3 illustrates the second transmission line 54 as having a connection to electrical ground 58, but the second transmission line 54 may have any voltage potential that suits the service provided by the telephony network 50.

The telephony network 50 receives electrical power from both the photovoltaic power source 22 and from the rectifier 24. The rectifier 24 receives AC electrical power from the electric grid 26 and converts the AC electrical power to DC power. The rectifier 24 has a first output terminal 70 connected to the first transmission line 52 and a second output terminal 72 connected to the second transmission line 54. The photovoltaic power source 22 converts optical energy (e.g., sunlight if a solar panel) into DC voltage. The DC voltage from the photovoltaic power source 22 is herein termed “photovoltaic power” to distinguish from the DC power produced by the rectifier 24. The photovoltaic power source 22 has a first terminal 74 connected to the first transmission line 52 and a second terminal 76 connected to the second transmission line 54.

The feedback mechanism 28 may again cause a reduction in the AC electrical power consumed by the rectifier 24. The feedback mechanism 28 determines the photovoltaic power (e.g., current and/or voltage) produced by the photovoltaic power source 22. The feedback mechanism 28 also measures the DC power (e.g., current and/or voltage) produced by the rectifier 24. Because the photovoltaic power source 22 provides supplemental electrical power to the telephony network 50, the feedback mechanism 28 may reduce the DC output produced by the rectifier 24. When the rectifier 24 produces less DC output, the rectifier 24 may consume less AC electrical power from the electric grid 26. The electricity costs for operating the rectifier 24 are thus correspondingly reduced.

FIG. 3 illustrates a typical telephony plant. The one or more batteries 56 provide a biasing voltage to the first transmission line 52. The biasing voltage applied by the one or more batteries 56 may be a negative forty eight (−48) Volts DC, but the biasing voltage may be any value that suits the telephony network 50. The first transmission line 52 is thus connected in parallel with the one or more batteries 56, with the photovoltaic power source 22, and with the rectifier 24. The second transmission line 54 creates a parallel connection to the electrical ground 58 for the photovoltaic power source 22 and for the rectifier 24. In the −48 Volts DC telephony power plant, the telephone power charge and discharge busses may be connected in parallel to the photovoltaic power source 22. The parallel connections may be made at the main charge battery bus and at the main charge ground bus. Because the photovoltaic power source 22 provides additional electrical power to the telephony network 50, the rectifier 24 may consume less AC electrical power from the electric grid 26. The electricity costs for operating the telephony network 50 are thus reduced.

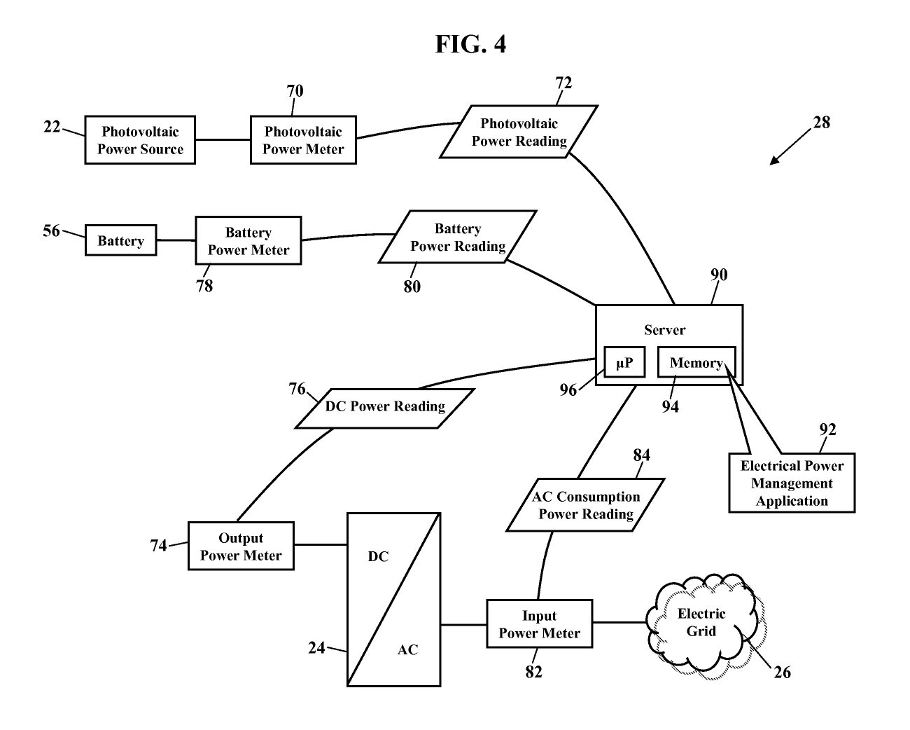

FIG. 4 is a block diagram further illustrating the feedback mechanism 28, according to exemplary embodiments. The feedback mechanism 28 may comprise one or more devices that read or measure current, voltage, and/or electrical power. FIG. 4, for example, illustrates a photovoltaic power meter 70 that reads or measures the DC photovoltaic power (e.g., current and/or voltage) produced by the photovoltaic power source 22. The photovoltaic power meter 70 sends a photovoltaic power reading 72 to the feedback mechanism 28. Similarly, a rectifier output power meter 74 reads or measures the DC power (e.g., current and/or voltage) produced by the rectifier 24. The rectifier power meter 74 sends a DC power reading 76 to the feedback mechanism 28. A battery power meter 78 may measure the electrical power provided by the one or more batteries 56, and a battery power reading 80 is sent to the feedback mechanism 28. A rectifier input power meter 82 may measure the AC electrical power consumed by the rectifier 24, and an AC power consumption reading 84 is sent to the feedback mechanism 28.

The feedback mechanism 28 may include a processor-controlled device 90. The processor controlled device 90 is illustrated as a server, but later paragraphs will illustrate other devices. The processor controlled device 90 may store and execute an electrical power management application 92. The electrical power management application 92 may be stored in memory 94, and a processor 96 may communicate with the server's memory 94 and execute the electrical power management application 92. The electrical power management application 92 may receive the photovoltaic power reading 72, the DC power reading 76, the battery power reading 80, and/or the AC power consumption reading 84. The electrical power management application 92 may comprise methods, computer programs, and/or computer program products that monitor these readings to reduce the consumption of electricity by the rectifier 24, as the above paragraphs explained.

The processor-controlled device 90 is only simply illustrated. Because the architecture and operating principles of computers and processor-controlled devices are well known, their hardware and software components are not further shown and described. If the reader desires more details, the reader is invited to consult the following sources, all incorporated herein by reference: ANDREW TANENBAUM, COMPUTER NETWORKS (4^{th} edition 2003); WILLIAM STALLINGS, COMPUTER ORGANIZATION AND ARCHITECTURE: DESIGNING FOR PERFORMANCE (7^{th} Ed., 2005); and DAVID A. PATTERSON & JOHN L. HENNESSY, COMPUTER ORGANIZATION AND DESIGN: THE HARDWARE/SOFTWARE INTERFACE (3^{rd} Edition 2004).

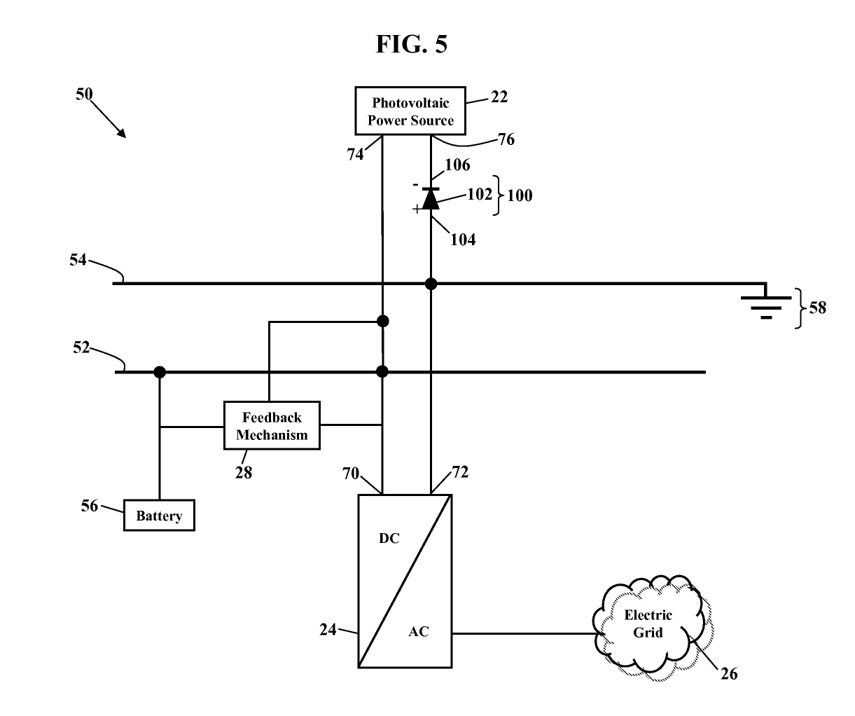

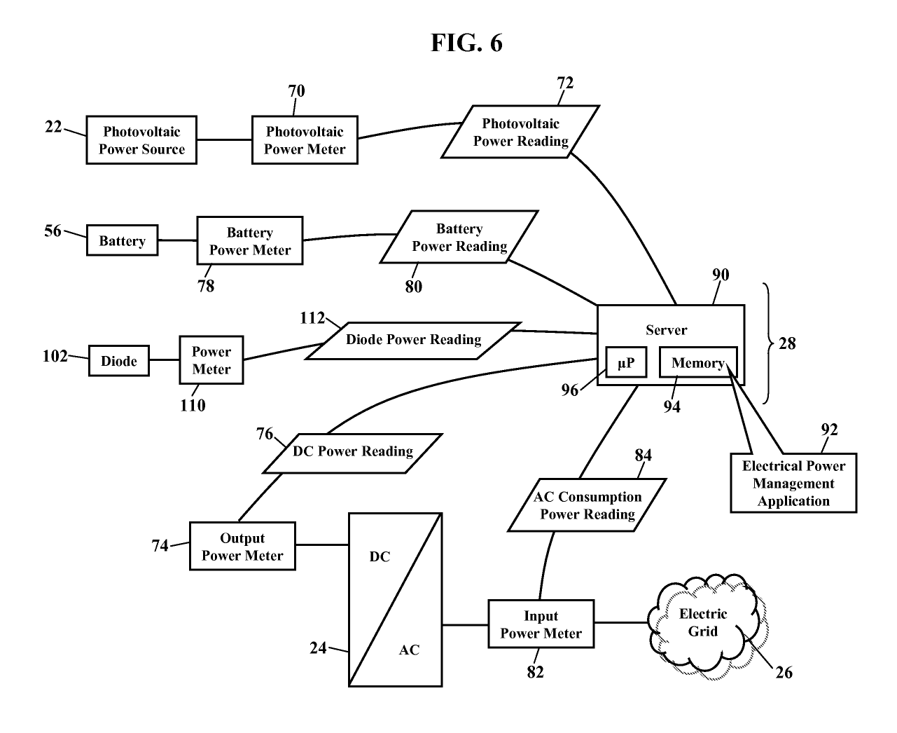

FIGS. 5 and 6 are more detailed schematic illustrating supplemental photovoltaic power for the telephony network 50, according to exemplary embodiments. FIG. 5 illustrates a unidirectional device 100 connected in series with the second transmission line 54 and with the second terminal 76 of the photovoltaic power source 22. The unidirectional device 100 is illustrated as a diode 102 having a first terminal 104 connected to the second transmission line 54 (and thus the electrical ground 58) and a second terminal 106 connected to the second terminal 76 of the photovoltaic power source 22. The diode 102 only permits current to flow in a single direction when properly biased. Only when the diode 102 is properly biased will current flow through the diode 102 and to or from the second transmission line 54 and the photovoltaic power source 22.

FIG. 6 illustrates the measurement of current flow in the diode 102. A power meter 110 is connected in series with the diode 102 to measure the electrical power in the diode 102. A diode power reading 112 is sent to the electrical power management application 92.

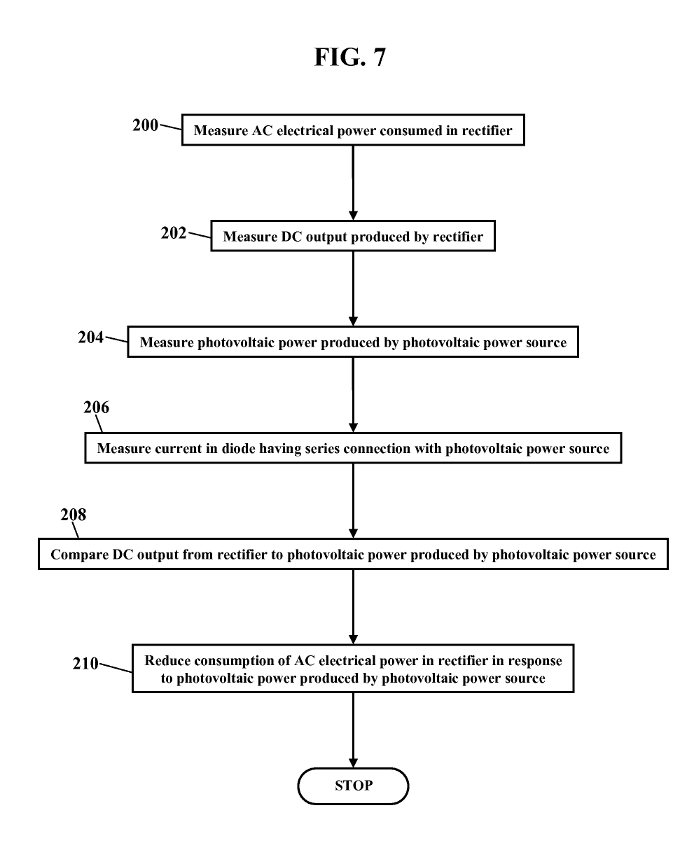

FIG. 7 is a flowchart illustrating a method of providing supplemental electrical power, according to exemplary embodiments. AC electrical power consumed in the rectifier 24 is measured (Block 200). A DC output produced by the rectifier 24 is measured (Block 202). Photovoltaic power produced by the photovoltaic power source 22 is measured (Block 204). Current is measured in a diode having a series connection to the photovoltaic power source 22 (Block 206). The DC output from the rectifier 24 is compared to the photovoltaic power produced by the photovoltaic power source 22 (Block 208). The consumption of the AC electrical power in the rectifier 24 is reduced in response to the photovoltaic power produced by the photovoltaic power source 22 (Block 210).

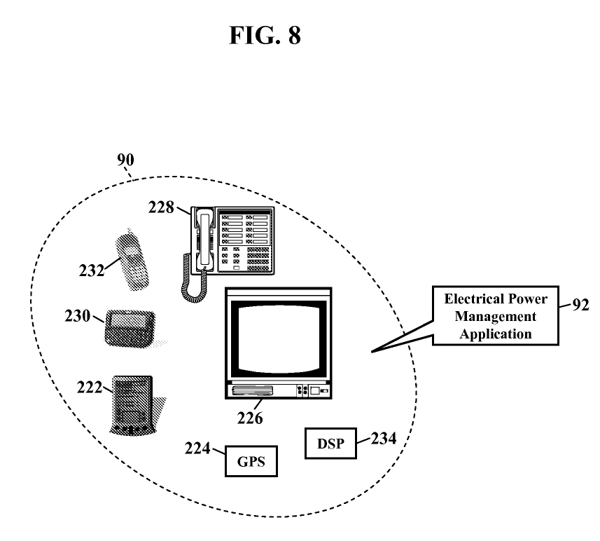

FIG. 8 is a schematic illustrating more processor-controlled devices 90. The electrical power management application 92 may operate in a personal digital assistant (PDA) 222, a Global Positioning System (GPS) device 224, an interactive television 226, an Internet Protocol (IP) phone 228, a pager 230, a cellular/satellite phone 232, or any computer system and/or communications device utilizing a digital signal processor (DSP) 234. The processor-controlled device 90 may also include watches, radios, vehicle electronics, clocks, printers, gateways, and other apparatuses and systems.

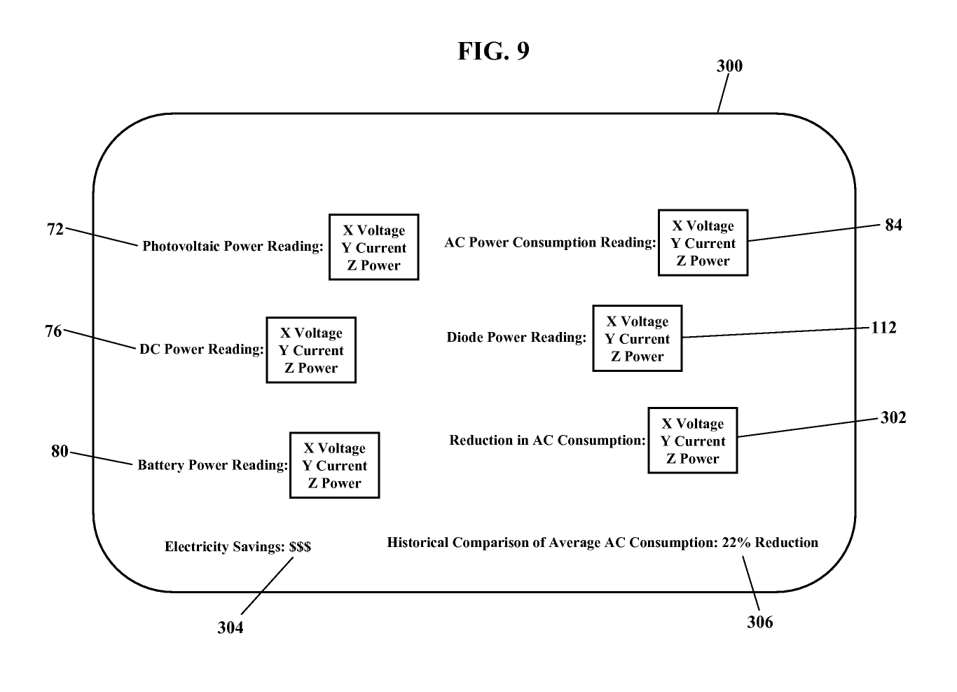

FIG. 9 is a schematic illustrating a graphical user interface 300, according to exemplary embodiments. The graphical user interface 300 may be displayed by any of the processor-controlled devices 90 illustrated in FIGS. 4, 6, and 8. The graphical user interface 300 may be produced by the electrical power management application (illustrated as reference numeral 92 in FIGS. 4, 6, and 8). The graphical user interface 300 may visually display the photovoltaic power reading 72, the DC power reading 76, the battery power reading 80, the AC power consumption reading 84, and/or the diode power reading 112. The graphical user interface 300 may also present a calculated or actual reduction 302 in AC electrical power consumption due to the photovoltaic power reading 112. The graphical user interface 300 may also present a financial savings calculation 304 and even a historical comparison 306 of electrical usage. Management, for example, may use the financial savings calculation 304 to determine an investment payback for the photovoltaic power source 22.

Exemplary embodiments may be physically embodied on or in a computer-readable storage medium. This computer-readable medium may include CD-ROM, DVD, tape, cassette, disk, memory card, and large-capacity disk. The computer-readable medium, or media, could be distributed to end-users, licensees, and assignees. A computer program product for providing photovoltaic power comprises the computer-readable medium and processor-readable instructions, as the above paragraphs explained.

While exemplary embodiments have been described with respect to various features, aspects, and embodiments, those skilled and unskilled in the art will recognize exemplary embodiments are not so limited. Other variations, modifications, and alternative embodiments may be made without departing from the spirit and scope of the claims.

What is claimed is:

1. A method of providing photovoltaic power in a communications network, comprising:
consuming alternating current (AC) electrical power at a rectifier in the communications network;
receiving photovoltaic power produced by a photovoltaic device; and
reducing the consumption of the AC electrical power in response to the photovoltaic power produced by the photovoltaic device.

2. The method according to claim 1, further comprising applying the photovoltaic power produced by the photovoltaic device to a first transmission line of the communications network.

3. The method according to claim 2, further comprising rectifying the AC electrical power to produce a direct current (DC) output from the rectifier.

4. The method according to claim 3, further comprising applying the DC output from the rectifier to the first transmission line of the communications network.

5. The method according to claim 4, further comprising applying a voltage source to the first transmission line.

6. The method according to claim 5, further comprising providing an electrical connection to electrical ground for the rectifier, the photovoltaic device, and the voltage source.

7. The method according to claim 6, further comprising measuring current flowing through a unidirectional device connected in series between the photovoltaic device and the electrical connection to electrical ground.

8. The method according to claim 6, further comprising measuring current flowing through a diode having a first terminal connected to the electrical connection to electrical ground and a second terminal connected to a ground connection at the photovoltaic device.

9. A system providing photovoltaic power to a communications network, comprising:
a rectifier consuming an alternating current (AC) input to produce a direct current (DC) output;
a photovoltaic device producing an output; and
a first transmission line providing a parallel connection between the DC output from the rectifier and the output from the photovoltaic device,
wherein the AC input consumed by the rectifier is reduced by an amount of power produced by the output of the photovoltaic device.

10. The system according to claim 9, further comprising a second transmission line providing an electrical connection to electrical ground for the rectifier and for the photovoltaic device.

11. The system according to claim 10, further comprising a unidirectional device connected in series between the photovoltaic device and the electrical connection to electrical ground.

12. The system according to claim 10, further comprising a diode having a first terminal connected to the electrical connection to electrical ground and a second terminal connected to a ground connection the photovoltaic device.

13. The system according to claim 9, further comprising a voltage source connected to the first transmission line that provides a biasing voltage.

14. The system according to claim 9, further comprising a DC voltage source connected to the first transmission line that provides a DC biasing voltage.

15. The system according to claim 9, further comprising an electrical power controller having a first input, a second input, and an output, the first input connected to the DC output from the rectifier, the second input connected to the output from the photovoltaic device, and the output connected to the rectifier, the electrical power controller comparing the output from the photovoltaic device to the DC output from the rectifier and reducing the DC output from the rectifier by the amount of power produced by the output of the photovoltaic device.

16. A computer program product comprising a computer readable storage medium storing processor-executable instructions for performing a method of providing photovoltaic power to a communications network, comprising:
measuring consumption of alternating current (AC) electrical power in a rectifier that produces a direct current (DC) output to a telephony transmission line;
measuring the DC output in the telephony transmission line;
measuring photovoltaic power produced by a photovoltaic device that is applied to the telephony transmission line; and
reducing the consumption of the AC electrical power in the rectifier in response to the photovoltaic power produced by the photovoltaic device.

17. The computer program product according to claim 16, further comprising instructions for comparing the DC output from the rectifier to the photovoltaic power produced by the photovoltaic device.

18. The computer program product according to claim 16, further comprising instructions for reducing the DC output from the rectifier by an amount equal to the photovoltaic power produced by the photovoltaic device.

19. The computer program product according to claim 16, further comprising instructions for applying a biasing voltage to the telephony transmission line.

20. The computer program product according to claim 16, further comprising instructions for measuring current in a diode having a first terminal connected to electrical ground and a second terminal connected to the photovoltaic device.
